(19) United States
(12) Patent Application Publication
(10) Pub. No.: US 2006/0152908 A1
(43) Pub. Date: Jul. 13, 2006

(54) Mobile computer attachment apparatus

(76) Inventors: Viktors Berstis, Austin, TX (US); Randolph Michael Forlenza, Austin, TX (US); John Paul Kaemmerer, Pflugerville, TX (US)

Correspondence Address: IBM CORPORATION (DWL);C/O LALLY & LALLY, L.L.P., P. O. BOX 684749, AUSTIN, TX, 78768-4749, US

(21) Appl. No.: 11/034,555

(22) Filed: Jan. 13, 2005

(51) Int. Cl. H05K 7/16

(52) U.S. Cl. 361/725; 361/724

(57) ABSTRACT

A brick apparatus for use with a mobile computer includes a chassis having a connection panel and means for attaching the connection panel to a connection panel of the mobile computer. A power transformer is located within the chassis to produce a DC signal from an AC input. A retractable power cord of the brick is connected at one end to the transformer and connectable at a second end to an AC outlet. A DC power pin connected to the DC signal of the power transformer is positioned to engage a DC power jack of the mobile computer when the apparatus is attached to the mobile computer panel. The apparatus may further include a retractable locking cable and retractable network connections. The apparatus may include pass through connectors to provide external access to connectors of the mobile computer rear panel and a battery to provide power to the mobile computer.

### RELATED APPLICATION

The subject matter disclosed herein is related to the subject matter disclosed in U.S. patent application Ser. No. 10/824,990, entitled Device Carrying System, Barnes et al., filed Apr. 15, 2004.

### BACKGROUND

1. Field of the Present Invention

The present invention is in the field of data processing systems and, more particularly, mobile data processing systems such as laptop and notebook computers.

2. History of Related Art

Mobile computers including laptop and notebook computers are marketed and designed to be highly transportable. The transportability of a mobile computer, however, can be limited by the number of attachment devices that must be carried with a mobile computer to make it functional and secure. Typically, for example, mobile computer users must carry an AC adapter to charge the computer's battery and to power the computer when the battery is weak or dead. Many mobile computer users also routinely carry securing mechanisms such as cable locks to prevent loss or theft of the computer system. Users may also carry network attachment apparatus such as Ethernet cabling or phone cables to connect the system to a network port. Because all of these necessary or desirable attachments are bulky or cumbersome, the transportability of a mobile computer system is substantially reduced. It would be desirable to implement a mobile computer and an integrated or removable attachment device that addressed these issues.

### SUMMARY OF THE INVENTION

The identified objective is achieved in the present invention with an attachable apparatus or brick for use with a mobile computer. The brick includes a chassis having a front panel and means for attaching the brick front panel to a rear panel of the mobile computer. In other embodiments, the brick may attach to a side or even a front panel of the mobile computer. A power transformer is located within the chassis to produce a DC signal from an AC input. A retractable power cord of the brick is connected at one end to the transformer and connectable at a second end to an AC outlet. A DC power pin connected to the DC signal of the power transformer is positioned to engage a DC power jack of the mobile computer when the brick is attached to the mobile computer panel. The brick may further include a retractable locking cable and retractable modem and/or network connections. The brick may include pass through connectors to provide external access to connectors of the mobile computer rear panel. Alternatively, the brick chassis may define a cutout or void that aligns with at least some connectors on a rear panel of the mobile computer when the brick is attached to the mobile computer, wherein the void permits external access to the connectors.

### BRIEF DESCRIPTION OF THE DRAWINGS

Other objects and advantages of the invention will become apparent upon reading the following detailed description and upon reference to the accompanying drawings in which:

FIG. 1 is a top view of a mobile computer suitable for use with an attachable brick apparatus according to an embodiment of the present invention;

FIG. 2 is a side view of the mobile computer of FIG. 1;

FIG. 3 is a rear view of the mobile computer of FIG. 1;

FIG. 4 is a top view of an assembly including the mobile computer of FIG. 1 and an attachable brick device according to an embodiment of the present invention;

FIG. 5 is a rear view of the attachable brick apparatus of FIG. 4;

FIG. 6 is a rear view of an alternative embodiment of the attachable brick apparatus;

FIG. 7 is a top view of the assembly of FIG. 4 emphasizing carrying straps of the brick apparatus.

While the invention is susceptible to various modifications and alternative forms, specific embodiments thereof are shown by way of example in the drawings and will herein be described in detail. It should be understood, however, that the drawings and detailed description presented herein are not intended to limit the invention to the particular embodiment disclosed, but on the contrary, the intention is to cover all modifications, equivalents, and alternatives falling within the spirit and scope of the present invention as defined by the appended claims.

### DETAILED DESCRIPTION OF THE INVENTION

Generally speaking, the present invention is a detachable, portable apparatus or “brick” for use with a mobile computer system. The brick attaches to a side or panel of a mobile computer, usually the rear panel (although the brick could attach to a side panel or front panel), and incorporates one or more elements that facilitate the operation, functionality, or security of the system. The brick would preferably include an AC adapter or power transformer that produces a DC voltage suitable for operating the mobile computer. When the brick is attached to the mobile computer panel, a probe connected to the output of the AC adapter mates with a DC power input port on the panel. The brick might further include one or more extendible connectors for connecting the brick to a phone jack, a network jack, or an AC power outlet. In a “pass through” embodiment, the brick includes connectors corresponding to various connectors found on the rear panel of the mobile computer. When the brick is attached, the brick connectors are mated to the mobile computer connectors. The brick may further include an extendible cable lock mechanism and a cable lock probe or pin that mates with a cable lock opening in the mobile computer chassis. The brick may further include straps that provide a means for carrying the mobile computer.

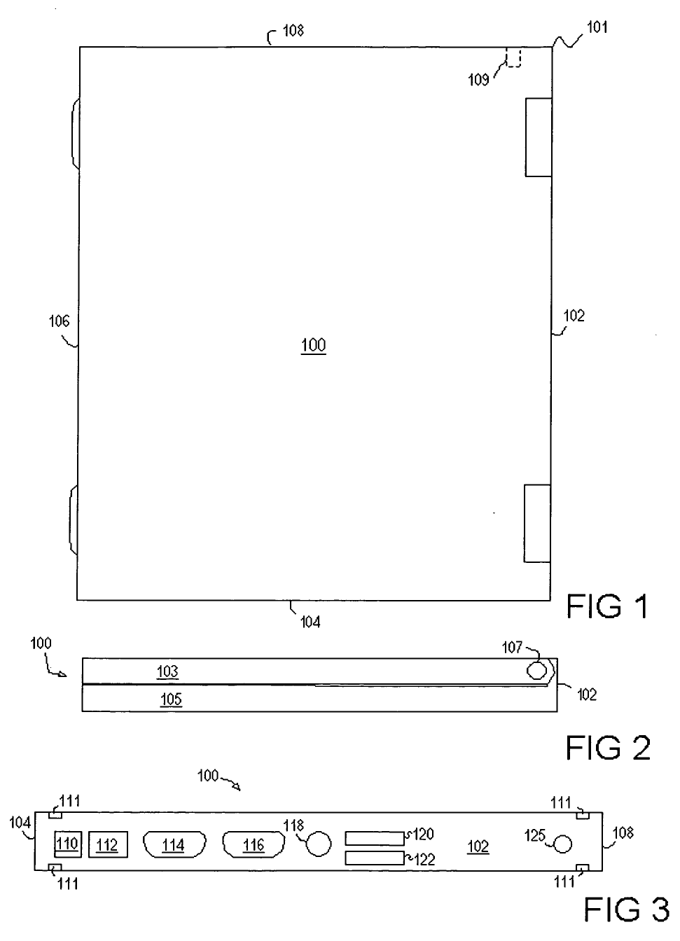

Turning now to FIG. 1 an exemplary top view of a mobile computer 100 is presented. Mobile computer 100 includes a substantially rectangular chassis 101 that includes a rear panel 102, a front panel 106 and side panels 104 and 108. As depicted in the side view of FIG. 2, mobile computer 100 includes first and second parts 103 and 105 that are hinged together with a hinge 107 near the rear panel 102. Hinge 107 enables first part 103, which likely includes the mobile computer's display screen, to rotate with respect to second part 105, which likely includes the mobile computer's keyboard and touchpad or other pointing device as will be familiar to users and owners of mobile computers.

Referring to FIG. 3, the depicted embodiment of mobile computer 100 includes a rear panel 102 that includes one or more connectors represented by reference numerals 110-125. Connector 110 is an RJ11 connector port, which is typically connected to a modem of the mobile computer and enables mobile computer 100 to access a network such as the Internet via a dial up connection. Connector 112 is an RJ45 connector port, which is usually connected to a network interface card or network adapter and enables mobile computer 100 to connect to an Ethernet (or other type) of local area network (LAN). Connectors 114 and 116 represent other types of connectors such as serial I/O connectors and/or video display connectors. Connector 118 may represent a keyboard or mouse connector enabling the user to attach an external keyboard or mouse to mobile computer 100. Connectors 120 and 122 represent first and second USB connectors and/or firewire enabling compliant connections to a microprocessor of mobile computer 100.

A DC power jack 125 of rear panel 102 is configured to receive a source of DC power, typically from the output of an AC adapter or transformer. Typically, mobile computer 100 is distributed and sold with a power adapter that connects to a conventional 120V AC outlet at one end, includes a transformer, and produces a relatively low voltage (i.e., typically less than 19V) DC signal at the output. The power adapter, when connected between DC power jack 125 and a source of 120 V AC power, charges a rechargeable DC power source (battery) of mobile computer 100 and provides an alternative power source for mobile computer 100 so that mobile computer 100 may be operated independent of the battery. The specific type, number, and arrangement of connectors on rear panel 102 of mobile computer 100 is an implementation detail and the present invention is not restricted to any particular implementation.

Rear panel 102 of mobile computer 100 further includes a set of slots 111 positioned and otherwise configured to receive a corresponding set of tabs of an attachable brick apparatus according to the present invention as described further in the following paragraphs. Although the embodiment of rear panel 102 depicted in FIG. 3 illustrates a set of four tabs 111, this is an implementation detail and alternative configurations may incorporate a different number and/or type of means for receiving an attachable apparatus.

Mobile computer users and owners will appreciate that, while the mobile computer chassis 101 may be adequately portable, the attachments required to power mobile computer 100 or its battery, secure mobile computer 100 to a fixed object, and connect mobile computer 100 to a network may be considerable in terms of their number. Moreover, many conventional mobile computer attachment elements such as an AC adapter are bulky and unwieldy. Similarly network connection mechanism such as phone cords and Ethernet cables are difficult to store conveniently when not in use. Thus, although mobile computer 100 is theoretically easy to transport, the attachment elements required are frequently cumbersome or difficult to store and transport in a compact and convenient manner.

The present invention addresses these issues by providing a brick apparatus that attaches to a panel of the mobile computer system. The brick preferably incorporates or integrates multiple attachment elements typically associated with a mobile computer. These incorporated or integrated attachment elements are required or desirable to operate or secure the system or connect the system to a network.

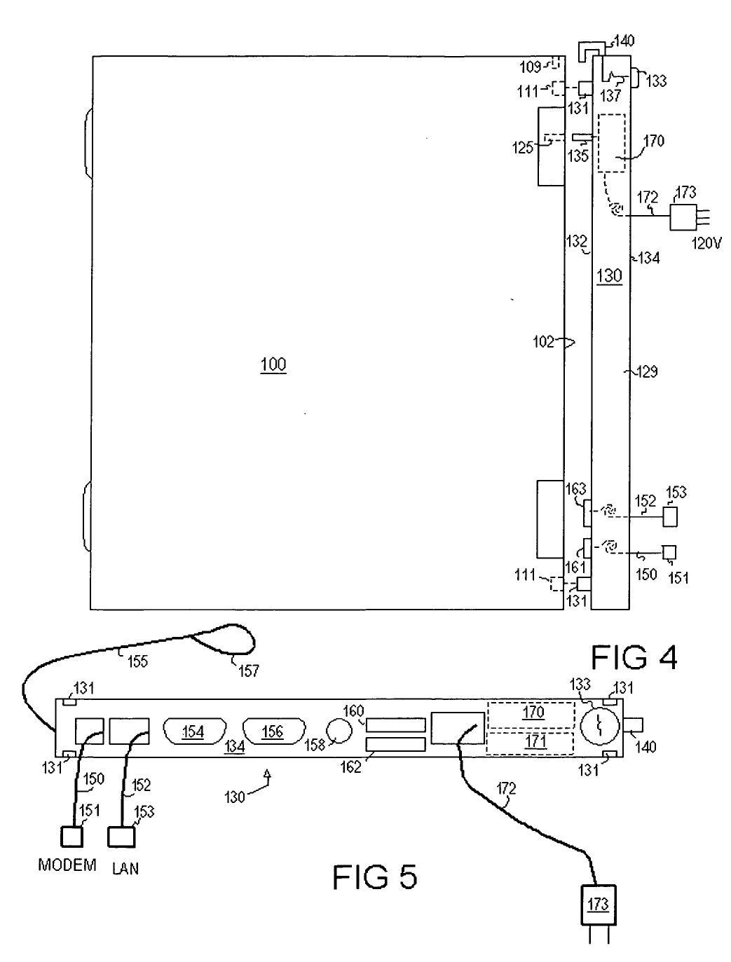

Referring now to FIG. 4, mobile computer 100 is shown in combination with attachable brick apparatus 130 according to an embodiment of the present invention. Brick apparatus 130 includes a chassis 129 that is preferably rectilinear. A rear view of attachable brick apparatus 130 is shown in FIG. 5. In the depicted embodiment, brick apparatus chassis 129 includes a front panel 132 and a rear panel 134. A set of attachment tabs 131 extends from front panel 132. Attachment tabs 131 are positioned to engage attachment slots 111 of the computer system rear panel 102 when brick 130 is properly positioned (aligned) with mobile computer 100 thereby providing a means for attaching brick 130 to a panel of mobile computer 100.

As depicted in FIG. 5, the dimensions of brick 130 conform to the dimensions of mobile computer rear panel 102. In this embodiment, the exterior brick 130, when attached to mobile computer rear panel 102 is continuous with the exterior of mobile computer 100. In other embodiments, the dimensions of brick 130 may be larger or smaller than the dimensions of mobile computer 100.

The embodiment depicted FIG. 5 is a “pass through” embodiment in which rear panel 134 of brick 130 includes connectors (154, 156, 158, 160, and 162) corresponding to one or more of the connectors (114, 116, 118, 120, and 122) on mobile computer rear panel 102 (see FIG. 3). When brick 130 is attached to mobile computer rear panel 102, these pass through connectors on brick rear panel 134 provide extensions of the corresponding connectors on mobile computer rear panel 102 so that a user may connect to the mobile computer rear panel connectors by connecting to the corresponding connectors in the brick rear panel 134.

In addition to the pass through connectors 154-162, brick 130 as depicted in FIG. 5 includes one or more extendible and retractable wires or cables. Specifically, the depicted embodiment of brick 130 includes an extendible and retractable modem cable 150. Modem cable 150 includes at its extremity an RJ11 plug 151 that may be used to plug modem cable 150 into a phone jack in a wall or other external connection. Internally, brick 130 provides a connection between extendible and retractable modem cable 150 and a RJ11 plug 161 positioned on front panel 132. Plug 161 is positioned and configured to mate with the RJ11 jack 110 of mobile computer rear panel when brick 130 is attached to mobile computer 100. Extendible and retractable modem cable 150, as its name implies, may be retracted within brick 130 when not in use and extended to varying lengths to connect RJ11 plug 151 to a wall jack when in use. Modem cable 150 and RJ11 plug 151 provide a means for connecting a modem (not depicted) of computer system 100 to an external phone line while eliminating the need to carry a phone cord with mobile computer 100.

The depicted embodiment of brick 130 includes an extendible and retractable network cable 152 that connects to an RJ45 plug 153 at its extendible end and to an RJ45 plug 163 positioned on brick front panel 132. Plug 163 is positioned and configured to mate with the RJ45 jack 112 of mobile computer rear panel 102 when brick 130 is attached to mobile computer 100. Analogous to the modem cable 150, extendible and retractable network cable 152 may be retracted within brick 130 when not in use and extended to varying lengths when in use. Network cable 152 and RJ45 plug 153 provide a means for connecting a network interface card (NIC) or network adapter (not depicted) of computer system 100 to an external LAN while eliminating the need to carry an Ethernet or other network cable with mobile computer 100.

The depicted embodiment of brick 130 further incorporates an extendible and retractable locking cable 155. Locking cable 155 is preferably of steel cable construction that is difficult to sever. Locking cable 155 includes a locking mechanism 157 suitable for attaching to a fixed object (an office desk or a seat in, for example) to secure attachment brick 130 to the desk. The depicted embodiment of locking mechanism 157 is a looped cable, locking mechanism 157 may be implemented with a conventional keyed or combination lock or with other suitable locking means. In addition, the depicted embodiment of attachment brick 130 includes a locking tab 140 and a corresponding locking slot 133 and corresponding locking mechanism 137 the enables brick 130 to securely engage a cable lock slot 109 of mobile computer 100 so that brick 130 cannot be disengaged from mobile computer 100 when locking mechanism 137 is activated (such as by turning a cable lock key). By providing a retractable locking cable 155 and a mechanism for locking brick 130 to mobile computer 100, brick 130 relieves the mobile computer owner from having to transport bulky and relatively heavy conventional cable lock devices.

The depicted embodiment of brick 130 includes an extendible and retractable power cable 172 that includes an AC power plug 173 at its extendible end. Internal to brick 130 (i.e., within the chassis 129 of brick 130), extendible power cable 172 connects to a transformer 170 that produces a DC output signal from a conventional 120 or 240 V AC input signal. The transformer DC output signal is connected to a DC power plug 135 on front face 132 of brick 130. DC power plug 135 is positioned to mate with the DC power jack 125 on rear face 102 of when brick 130 is attached to rear panel 102 of mobile computer 100. Extendible and retractable power cable 172, together with the internal transformer 170, eliminate the need to transport an external power transformer and its associated power cords with mobile computer 100. Instead, power cable 172 is extended from brick 130 and plugged into a conventional AC outlet when brick 130 is attached to mobile computer to provide an external source of power to mobile computer 100.

The embodiment of brick 130 depicted in FIG. 4 also includes a battery 171. Battery 171 may provide a source of back up power for the mobile computer's internal battery. Battery 171, for example, may be tapped when the mobile computer internal battery is dead or weak. Battery 171 may, in another embodiment, replace the mobile computer battery entirely. Battery 171 could also function to supply a low level of power when mobile computer 100 is in a standby power state.

While brick 130 as shown in FIG. 4 and FIG. 5 is a detachable apparatus that is suitable for use as an add-on feature for an existing mobile computer, other implementations may integrate some or all of the features of brick 130 into the chassis of the mobile computer system. In this integrated embodiment, the pass through connectors 154, 156, 158, 160, and 162 described above would be unnecessary and the retractable locking cable 155, modem cable 150, network cable 152, and power cable 172 would be integrated into mobile computer 100. In addition, although certain retractable cables are depicted, brick 130 is suitable for incorporating additional retractable cables such as a retractable mouse cable that connects to a mouse connector on the mobile computer rear face. Brick 130 could also incorporate a wireless mouse port.

It will be appreciated that the embodiment of brick 130 depicted in FIG. 5 includes a considerable amount of connection hardware in the form of pass through connectors 154-162. This hardware adds undesirable cost to brick 130. In addition, the pass through embodiment is suitable for use only with a mobile computer having a rear panel that mirrors the pass through connection hardware. In other embodiments, it may be desirable to reduce the cost of brick 130 by reducing the amount of connection hardware. It may also be desirable to make a brick 130 that is able to connect to more than one specific rear panel configuration.

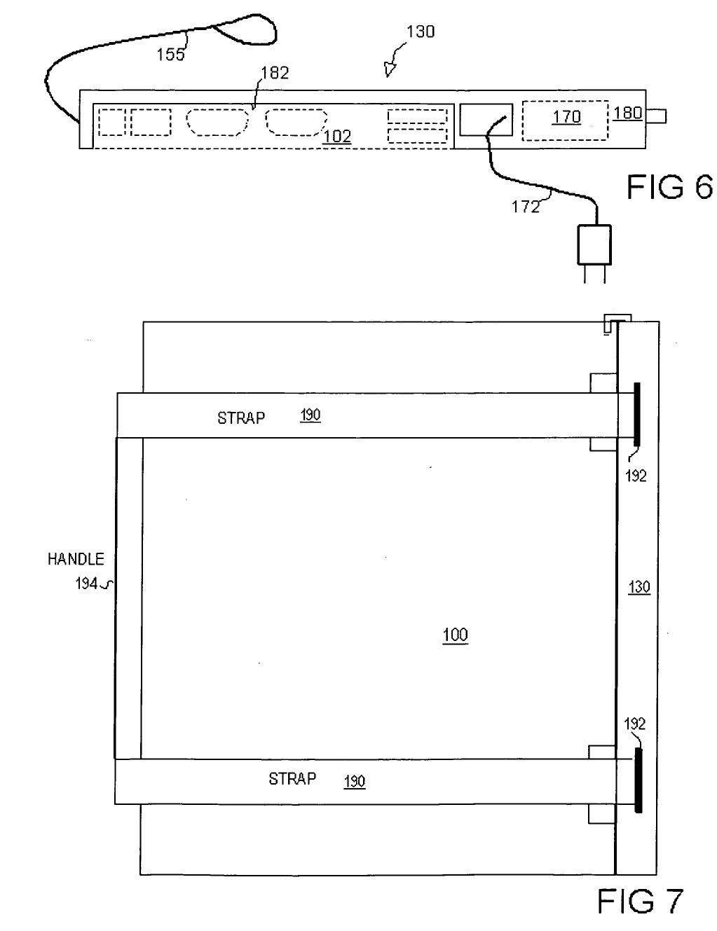

Referring now to FIG. 6, a generic embodiment of brick 130 is depicted. In the embodiment depicted in FIG. 6, a chassis 180 of brick 130 defines a recess or void that aligns with some or all of the connectors 110-125 of mobile computer rear panel 102. In this embodiment, brick 130 permits access to at least some of the rear panel connectors on rear panel 102 when brick 130 is attached. This embodiment beneficially eliminates potentially costly passthrough connection hardware and is suitable for use with a potentially wider array of mobile computers since the brick does have to conform to a particular arrangement of rear panel connectors.

The embodiment of generic brick 130 depicted in FIG. 6 does retain the extendible and retractable locking cable 155, the extendible and retractable power cable 172 (and internal transformer 170), and the locking tab 140 and locking mechanism 137 described above with respect to FIG. 5. In this embodiment, a front panel of generic brick 130 would include a DC power plug analogous to the DC power plug 135 of the brick 130 described above with respect to FIG. 5.

Turning now to FIG. 7, an embodiment of brick 130 includes a set of retractable straps 190. Straps 190 providing a mechanism for carrying mobile computer 100 and brick 130. In the depicted embodiment, a pair of straps 190 extends from a corresponding pair of openings 192 in the chassis of brick 130. A complementary pair of straps (not shown) extends from the opposing side of brick 130. A cross member 194 is connected between the straps 190. The cross member 194 is grasped by the mobile computer's owner when the straps 190 are extended. In this manner, straps 190 and cross member 194 provide a retractable carrying mechanism for mobile computer 100. Straps 190 may be of any suitable material including, as examples, cloth, leather, or a synthetic material. Cross member 194 is preferably a rigid or semi-rigid member formed of steel, plastic, fabric, or the like. Straps 190 may also be implemented as detachable straps (using Velcro, zipper, snaps, or the like) that may be removed when the mobile computer is not being transported.

It will be apparent to those skilled in the art having the benefit of this disclosure that the present invention an attachment apparatus for a mobile computer. It is understood that the form of the invention shown and described in the detailed description and the drawings are to be taken merely as presently preferred examples. It is intended that the following claims be interpreted broadly to embrace all the variations of the preferred embodiments disclosed.

1. An apparatus for use with a mobile computer, comprising:
a chassis having a front panel wherein the front panel includes at least two connectors for connecting to corresponding connectors on the panel of the mobile computer;
attachment means for attaching and locking the apparatus front panel to a rear panel of the mobile computer;
a power transformer within the chassis to produce a DC signal from an AC input;
a retractable power cord connected at one end to the transformer and connectable at a second end to an AC outlet; and
a DC power pin on the front panel connected to the DC signal of the power transformer and positioned to engage a DC power jack on the rear panel of the mobile computer when the apparatus is attached to the mobile computer panel.

2. The apparatus of claim 1, wherein the apparatus chassis is continuous with a chassis of the mobile computer when the apparatus is attached to the mobile computer.

3. The apparatus of claim 1, further comprising a retractable locking cable, wherein the locking cable is extendible to attach the apparatus to an external object.

4. The apparatus of claim 3, further comprising:
a locking tab positioned to engage a cable lock slot of the mobile computer when the apparatus is attached to the device; and
a locking mechanism for securely engaging the locking tab in the cable lock slot to prevent the apparatus from being detached from the mobile computer.

5. The apparatus of claim 4, further comprising a retractable network connector connectable at a first end to an external LAN jack and connected at a second end to a network connection plug on the apparatus front panel, wherein the network connection plug is positioned to engage a network connection jack on the rear panel of the mobile computer when the apparatus is attached to the computer.

6. The apparatus of claim 5, further comprising a retractable modem connector connectable at a first end to an external phone jack and connected at a second end to a modem connection plug on the apparatus front panel, wherein the mobile connection plug is positioned to engage a modem connection jack on the rear panel of the mobile computer when the apparatus is attached to the computer.

7. The apparatus of claim 1, faker comprising a pass through connector mechanism positioned and configured to connect to a corresponding connector on a rear panel of the mobile computer when the apparatus is attached to the mobile computer and further configured to provide a functionally equivalent connection on the rear panel of the apparatus.

8. (canceled)

9. An attachable brick for use with a mobile computer, comprising:
a brick chassis including a front face wherein the brick chassis front face contacts a panel of the mobile computer when the brick is attached to the mobile computer and wherein the front face of the attachable brick includes at least two connectors for connecting to corresponding connectors on the panel of the mobile computer;
an AC power adapter within the chassis, wherein a DC signal produced by the power adapter is electrically connected to a DC power plug on the brick chassis front panel and further wherein the power plug aligns with a DC power jack on the mobile computer panel when the brick is attached to the mobile computer; and
a power cord connectable at a plug end to a source of AC power and connected at an opposing end to the AC power adapter in the brick.

10. The attachable brick of claim 9, wherein the power cord is retractable within the brick chassis.

11. The attachable brick of claim 9, further comprising a retractable locking cable connected to the brick and a locking mechanism suitable for locking the brick to the mobile computer.

12. The attachable brick of claim 9, further comprising a battery configured to provide power to the mobile computer.

13. The attachable brick of claim 9, further comprising a retractable cable suitable for connecting the brick to an external network.

14. The attachable brick of claim 13, further comprising a network plug connected to the retractable cable, wherein the network plug mates with a network jack of the mobile computer when the brick is attached to the mobile computer.

15. The attachable brick of claim 9, further comprising a set of straps connected to the brick, wherein the straps are suitable for holding the mobile computer when the brick is attached.

16. The attachable brick of claim 15, wherein the straps are retractable within the brick chassis.

17. (canceled)

18. An apparatus for use with a mobile computer, comprising:
an attachment mechanism for aching a front panel of the apparatus to a rear panel of the mobile computer;
at least two connectors on the front panel for connecting to corresponding connectors on the rear panel of the mobile computer:
a mechanism for securing the apparatus to the mobile computer;
a retractable mechanism for securing the apparatus to an external object; and
a retractable mechanism for connecting to a source of AC power.

19. The attachment apparatus of claim 18, further comprising a retractable mechanism for connecting to an external network.

20. The attachment apparatus of claim 18, finer comprising a set of retractable or detachable carrying straps suitable for carrying the mobile computer and the apparatus when the apparatus is attached to the mobile computer.

21. The attachment apparatus of claim 18, further comprising a pass through connector providing pass through access to a connector of the mobile computer rear panel.

22. The attachment apparatus of claim 18, further comprising a battery for providing power to the mobile computer.
